(19) United States
(12) Patent Application Publication
(10) Pub. No.: US 2026/0052874 A1
(43) Pub. Date: Feb. 19, 2026

(54) DISPLAY PANEL AND DISPLAY APPARATUS

(71) Applicant: Hefei Visionox Technology Co., Ltd., Hefei (CN)

(72) Inventors: Haohan ZHANG, Hefei (CN); Yuan YAO, Hefei (CN)

(73) Assignee: Hefei Visionox Technology Co., Ltd., Hefei (CN)

(21) Appl. No.: 19/299,271

(22) Filed: Aug. 13, 2025

(30) Foreign Application Priority Data
Aug. 19, 2024 (CN) 202411140201.1

(51) Int. Cl. H10K 59/35

(52) U.S. Cl. CPC H10K 59/353; H10K 59/352

(57) ABSTRACT

The present application relates to a display panel and a display apparatus. The display panel includes a light-transmitting active area, the light-transmitting active area including a plurality of first regions, and the plurality of first regions being arranged in an array, where each first region includes at least one opening area and at least one pixel area, and the display panel is provided with at least one sub-opening in the opening area; the pixel area includes at least one first sub-pixel, at least one second sub-pixel, and at least one third sub-pixel; and the first sub-pixel, the second sub-pixel, and the third sub-pixel are respectively used to emit light of different colors. The present application can ensure the display effect of the light-transmitting active area to the greatest extent, while increasing the light transmittance of the light-transmitting active area.

### CROSS-REFERENCE TO RELATED APPLICATIONS

The present application claims priority to Chinese Patent Application No. 202411140201.1, entitled “DISPLAY PANEL AND DISPLAY APPARATUS” and filed on Aug. 19, 2024, the entire contents of which are incorporated herein by reference.

### FIELD

The present application relates to the field of display, and in particular to a display panel and a display apparatus.

### BACKGROUND

With an increasing high requirement for high screen-to-body ratios, full-screen displays and narrow bezels have become mainstream design trends. In the related art, an under-display camera (UDC) technology has been proposed, where a camera is placed beneath a screen body. The UDC technology eliminates the need to place the camera in a bezel of a device such as a smartphone, thereby achieving a full-screen device. Generally, a higher light transmittance of the screen body is needed for achieving high image quality of the camera.

### SUMMARY

In view of this, a display panel and a display apparatus are provided to solve the above problems.

Embodiments of the present application provides a display panel, including:
a light-transmitting active area, the light-transmitting active area including a plurality of first regions, and the plurality of first regions being arranged in an array, where each first region includes at least one opening area and at least one pixel area, and the display panel is provided with at least one sub-opening in the opening area; the pixel area includes at least one first sub-pixel, at least one second sub-pixel, and at least one third sub-pixel; and the first sub-pixel, the second sub-pixel, and the third sub-pixel are respectively used to emit light of different colors.

In the display panel according to this embodiment of the present application, the light-transmitting active area includes the plurality of first regions arranged in an array, each first region includes at least one opening area and at least one pixel area, the pixel area includes at least one first sub-pixel, at least one second sub-pixel, and at least one third sub-pixel, and the opening area is provided with at least one sub-opening. This helps to increase a light transmittance of the light-transmitting active area; and this further helps the sub-pixels in the pixel area to form an RGB unit for light emission, thereby ensuring the display effects in the first regions. In conclusion, the present application can ensure the display effect of the light-transmitting active area to the greatest extent, while increasing the light transmittance of the light-transmitting active area.

One embodiment of the present application provides a display panel having an active area and a light-transmitting active area. The display panel includes:
a substrate; and
an isolation structure disposed on a side of the substrate, the isolation structure being provided with a plurality of isolation openings and a plurality of light-transmitting openings, where the isolation openings are located in the active area and the light-transmitting active area, and the isolation openings are configured to accommodate sub-pixels; and the light-transmitting openings are located in the light-transmitting active area, and a size of each light-transmitting opening is greater than a size of any one of the isolation openings.

In the display panel according to this embodiment of the present application, the isolation openings and the light-transmitting openings are disposed in the light-transmitting active area, where the isolation openings may accommodate the sub-pixels, and the light-transmitting openings can transmit ambient light. In this way, the light-transmitting openings in the light-transmitting active area help to increase the light transmittance of the light-transmitting active area; and the isolation openings in the light-transmitting active area may accommodate the sub-pixels, thereby ensuring that the light-transmitting active area has a specific display effect. In conclusion, the present application can ensure the display effect of the light-transmitting active area, while increasing the light transmittance of the light-transmitting active area.

An embodiment of the present application provides a display apparatus, including the display panel according to any one of the embodiments. The display apparatus can ensure the display effect of the light-transmitting active area, while increasing the light transmittance of the light-transmitting active area.

### BRIEF DESCRIPTION OF THE DRAWINGS

To describe the embodiments or exemplary embodiments of the present application more clearly, the following briefly describes the accompanying drawings required for describing the embodiments or the exemplary embodiments. Apparently, the accompanying drawings in the following description show merely some embodiments of the present application.

FIG. 1 is a schematic plan view of a display panel according to an embodiment of the present application;

FIG. 2 is a partial schematic plan view of a light-transmitting active area of a display panel according to an embodiment of the present application;

FIG. 3 is a schematic plan view of a first region in another light-transmitting active area of a display panel according to an embodiment of the present application;

FIG. 4 is a schematic diagram showing sub-pixel arrangement in an active area of the display panel shown in FIG. 2 and FIG. 3;

FIG. 5 is a partial schematic plan view of still another light-transmitting active area of a display panel according to an embodiment of the present application;

FIG. 6 is a partial schematic plan view of yet another light-transmitting active area of a display panel according to an embodiment of the present application;

FIG. 7 is a schematic diagram showing sub-pixel arrangement in an active area of the display panel shown in FIG. 6;

FIG. 8 is a partial schematic plan view of yet another light-transmitting active area of a display panel according to an embodiment of the present application;

FIG. 9A is a schematic diagram showing sub-pixel arrangement in an active area of the display panel shown in FIG. 8;

FIG. 9B is a partial schematic diagram of the sub-pixel arrangement shown in FIG. 9A;

FIG. 10 is a partial schematic plan view of yet another light-transmitting active area of a display panel according to an embodiment of the present application;

FIG. 11 is a partial schematic plan view of yet another light-transmitting active area of a display panel according to an embodiment of the present application;

FIG. 12 is a schematic diagram showing sub-pixel arrangement in an active area of the display panel shown in FIG. 11;

FIG. 13 is a partial schematic plan view of yet another light-transmitting active area of a display panel according to an embodiment of the present application;

FIG. 14 is a schematic diagram showing sub-pixel arrangement in an active area of the display panel shown in FIG. 13;

FIG. 15 is a partial schematic plan view of yet another light-transmitting active area of a display panel according to an embodiment of the present application;

FIG. 16 is a schematic diagram showing sub-pixel arrangement in an active area of the display panel shown in FIG. 15;

FIG. 17 is a partial schematic plan view of an isolation structure of the display panel shown in FIG. 15;

FIG. 18 is a partial schematic plan view of yet another light-transmitting active area of a display panel according to an embodiment of the present application;

FIG. 19 is a schematic diagram showing sub-pixel arrangement in an active area of the display panel shown in FIG. 18;

FIG. 20 is a partial schematic plan view of yet another light-transmitting active area of a display panel according to an embodiment of the present application;

FIG. 21 is a partial schematic plan view of yet another light-transmitting active area of a display panel according to an embodiment of the present application;

FIG. 22 is a schematic diagram showing sub-pixel arrangement in an active area of the display panel shown in FIG. 21;

FIG. 23 is a partial schematic plan view of yet another light-transmitting active area of a display panel according to an embodiment of the present application;

FIG. 24 is a partial schematic plan view of yet another light-transmitting active area of a display panel according to an embodiment of the present application;

FIG. 25 is a partial schematic plan view of yet another light-transmitting active area of a display panel according to an embodiment of the present application;

FIG. 26 is a partial schematic plan view of yet another light-transmitting active area of a display panel according to an embodiment of the present application;

FIG. 27 is a schematic diagram showing sub-pixel arrangement in an active area of the display panel shown in FIG. 24; and

FIG. 28 is a schematic diagram of a cross-sectional structure of a display panel according to an embodiment of the present application.

### LIST OF REFERENCE SIGNS

10: display panel; 10a: active area; 10al: second region; 10a11: first sub-region; 10a111: sub-region I; 10a112: sub-region II; 10a12: second sub-region; 10b: light-transmitting active area; 10b1: first region; 10b11: opening area; 10b111: first sub-opening area; 10b112: second sub-opening area; 10b12: pixel area; 11: substrate; 12: pixel unit; 121: sub-pixel; 1211: first electrode; 1212: light-emitting functional portion; 1213: second electrode; 121a: first sub-pixel; 121b: second sub-pixel; 121c: third sub-pixel; 13: isolation structure; 13a: opening group; 13b: isolation opening; 13b1: first isolation opening; 13b2: second isolation opening; 13b3: third isolation opening; 13c: light-transmitting opening; 131: isolation body; 132: blocking portion; 13: pixel defining layer; 14: array film layer; 15: sub-opening; 15a: first sub-opening; 15b: second sub-opening; 15c: third sub-opening.

### DETAILED DESCRIPTION OF THE EMBODIMENTS

For ease of understanding the present application, the present application will be described more comprehensively below with reference to relevant accompanying drawings. Embodiments of the present application are given in the accompanying drawings. However, the present application may be implemented in many different forms and is not limited to the embodiments described herein. Rather, these embodiments are provided for a more thorough and comprehensive understanding of the content disclosed in the present application.

It should be understood that although terms such as “first”, “second”, etc. may be used herein to describe various elements, these terms do not indicate any order, quantity, or importance, but are merely used to distinguish different components. These terms are merely used to distinguish one element from another. For example, without departing from the scope of the present application, a first element may be referred to as a second element, and similarly, a second element may be referred to as a first element. The term “comprise”, “include”, or similar expressions mean that the element or item preceding the term encompasses elements or items listed after the term and their equivalents, without excluding other elements or items.

Unless otherwise defined, all terms used herein shall have the same meanings as commonly understood in the art to which the present application belongs. The terms used herein in the description of the present application are merely for the purpose of describing some embodiments, and are not intended to limit the present application. The term “and/or” used herein includes any and all combinations of one or more of the associated listed items.

Reference is made to the relevant embodiments of the isolation structure disclosed in patents PCT/CN2023/134518, 202310909421.5, 202311616249.0, 202310773656.6, 202310707209.0, 202311346196.5, and 202310692671.8, the contents of which are incorporated herein by reference.

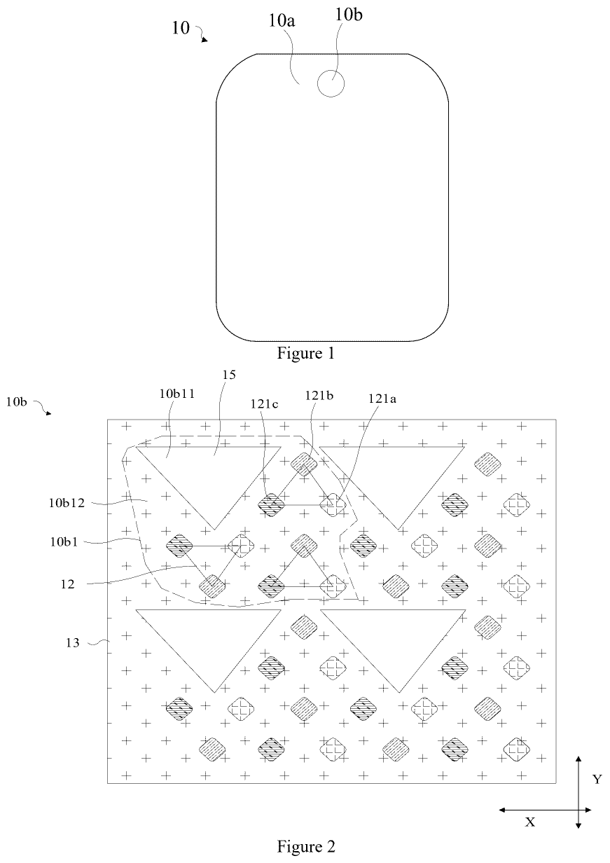

In one embodiment, referring to FIG. 1 and FIG. 2, an embodiment of the present application provides a display panel 10. The display panel 10 includes a light-transmitting active area 10b. The light-transmitting active area 10b includes a plurality of first regions 10b1, and the plurality of first regions 10b1 are arranged in an array. Each first region 10b1 includes at least one opening area 10b11 and at least one pixel area 10b12. The display panel 10 is provided with at least one sub-opening 15 in the opening area 10b11; the pixel area 10b12 includes at least one first sub-pixel 121a, at least one second sub-pixel 121b, and at least one third sub-pixel 121c; and the first sub-pixel 121a, the second sub-pixel 121b, and the third sub-pixel 121c are respectively used to emit light of different colors.

It can be understood that an under-display camera of a display apparatus may be disposed in the light-transmitting active area 10b. The shape of the light-transmitting active area 10b may be circular, rectangular, triangular, pentagonal, etc.

It should be noted that the shape of the first region 10b1 in the drawings of the embodiments of the present application is only schematic and does not mean that the shape of the first region 10b1 must be as shown in the drawings. It can be understood that the shape of the first region 10b1 may be a regular shape or an irregular shape. Within the first region 10b1, the opening area 10b11 is an area for forming an opening (such as providing the sub-opening 15) to increase a light transmittance, and the pixel area 10b12 is an area for providing a sub-pixel 121. The first sub-pixel 121a, the second sub-pixel 121b, and the third sub-pixel 121c may be different and each be one of: a red sub-pixel 121, a blue sub-pixel 121, or a green sub-pixel 121.

In the display panel 10 according to this embodiment of the present application, the light-transmitting active area 10b include the plurality of first regions 10b1 arranged in an array, each first region 10b1 includes at least one opening area 10b11 and at least one pixel area 10b12, the pixel area 10b12 includes at least one first sub-pixel 121a, at least one second sub-pixel 121b, and at least one third sub-pixel 121c, and the opening area 10b11 is provided with at least one sub-opening 15. This helps to increase a light transmittance of the light-transmitting active area 10b; and this further helps the sub-pixels 121 in the pixel area 10b12 to form an RGB unit for light emission, thereby ensuring the display effects in the first regions 10b1. In conclusion, the present application can ensure the display effect of the light-transmitting active area 10b to the greatest extent, while increasing the light transmittance of the light-transmitting active area 10b.

In one embodiment, a size of the opening area 10b11 is greater than or equal to a size of any sub-pixel 121. The sub-pixel 121 is any one of the first sub-pixel 121a, the second sub-pixel 121b, or the third sub-pixel 121c. Further, the size of the opening area 10b11 is greater than or equal to a size of the first sub-pixel 121a, the size of the opening area 10b11 is greater than or equal to a size of the second sub-pixel 121b, and the size of the opening area 10b11 is greater than or equal to a size of the third sub-pixel 121c.

In this way, the opening area 10b11 may be made large enough to facilitate the formation of a relatively large sub-opening 15 in the opening area 10b11, thereby increasing the light transmittance. It should be noted that in the related art, an opening, such as an ambient light opening or a fingerprint opening, is formed between adjacent sub-pixels to increase a light transmittance. However, a size of the opening is small, and the light transmittance of the opening is lower compared with that of the present application, which cannot meet light transmittance requirements of the under-display camera technology.

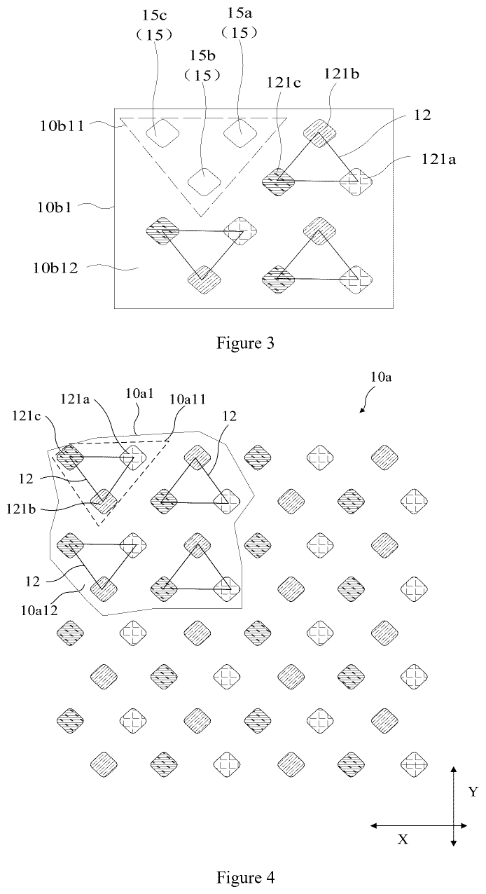

In one embodiment, as shown in FIG. 3, the opening area 10b11 includes a plurality of sub-openings 15. In this way, a total actual size of the opening area 10b11 is made relatively large, thereby increasing the light transmittance.

In one embodiment, the pixel area 10b12 includes at least one pixel unit 12, where the pixel unit 12 includes one first sub-pixel 121a, one second sub-pixel 121b, and one third sub-pixel 121c, or the pixel unit 12 includes one first sub-pixel 121a, one second sub-pixel 121b, and two third sub-pixels 121c.

It should be noted that the pixel unit 12 in the embodiments of the present application is used to emit colored light, and is formed by a red sub-pixel 121, a green sub-pixel 121, and a blue sub-pixel 121 together. In this way, the sub-pixels 121 in the pixel area 10b12 form one pixel unit 12 (RGB unit) for light emission, thereby ensuring the display effects in the first regions 10b1.

In one embodiment, the opening area 10b11 is provided with a plurality of sub-openings 15, and a number of sub-openings 15 is an integer multiple of a number of sub-pixels 121 contained in one pixel unit 12, the sub-pixels 121 including the first sub-pixel 121a, the second sub-pixel 121b, and the third sub-pixel 121c. For example, in the case in which the pixel unit 12 contains three sub-pixels 121, the number of sub-openings 15 may be 3, 6, 9, 12, etc.

In this way, a total actual size of the opening area 10b11 is made relatively large, thereby increasing the light transmittance.

In one embodiment, the plurality of sub-openings 15 include at least one first sub-opening 15a, at least one second sub-opening 15b, and at least one third sub-opening 15c; the first sub-opening 15a corresponds to the first sub-pixel 121a; the second sub-opening 15b corresponds to the second sub-pixel 121b; and the third sub-opening 15c corresponds to the third sub-pixel 121c. It should be noted that the sub-pixels 121 are usually arranged according to a specific rule. This is equivalent to removing the first sub-pixel 121a, the second sub-pixel 121b, and the third sub-pixel 121c originally located in the opening area 10b11, thereby making a configuration area of the sub-openings 15 match configuration positions of the sub-pixels 121 (the first sub-pixel 121a, the second sub-pixel 121b, and the third sub-pixel 121c), and more regular arrangement of the sub-openings 15 can be achieved and thus the consistency of light transmission performance is improved.

In one embodiment, an arrangement rule of the plurality of sub-openings 15 in the opening area 10b11 is the same as an arrangement rule of the sub-pixels 121 in one pixel unit 12 in the pixel area 10b12. In this way, the sub-openings 15 may be arranged more regularly, which is not only conducive to improving the consistency of the light transmission performance but also conducive to reducing the configuration difficulty of the sub-openings 15.

In one embodiment, a size of the first sub-opening 15a is equal to a size of the first sub-pixel 121a; a size of the second sub-opening 15b is equal to a size of the second sub-pixel 121b; and a size of the third sub-opening 15c is equal to a size of the third sub-pixel 121c. In this way, the configuration area of the sub-openings 15 can match the configuration positions of the sub-pixels 121 (the first sub-pixel 121a, the second sub-pixel 121b, and the third sub-pixel 121c), and more regular arrangement of the sub-openings 15 can be achieved and thus the consistency of light transmission performance is improved, and subsequent information collection of an under-display camera is ensured, while ensuring the display effect.

In one embodiment, a size of the opening area 10b11 is greater than or equal to a size of one pixel unit area in the corresponding first region 10b1, and all the sub-pixels 121 in the pixel unit 12 are located in the pixel unit area, where the pixel unit area refers to a configuration area of the pixel unit 12.

In this way, the opening area 10b11 may be made large enough to facilitate the provision of the sub-openings 15 in the opening area 10b11.

In one embodiment, referring to FIG. 2, the opening area 10b11 is provided with one sub-opening 15; and a size of the sub-opening 15 is greater than or equal to a sum of sizes of all the sub-pixels 121 in the pixel unit 12 in the corresponding first region 10b1. This is equivalent to making the size of one sub-opening 15 large enough and in a same total size of an opening area, a number of sub-openings 15 can be reduced, thereby lowering manufacturing costs of the sub-openings 15; and in addition, the light transmittance can be further increased, which is conducive to information collection of an under-display camera.

In one embodiment, a morphology of the opening area 10b11 is consistent with a contour of one pixel unit area in the corresponding first region 10b1. For example, when the contour of the pixel unit area is in the shape of a regular triangle, the contour morphology of the opening area 10b11 is in the shape of a regular triangle. In one embodiment, when the contour of the one pixel unit area is T-shaped (refer to FIG. 11), the contour morphology of the opening area 10b11 is T-shaped.

In one embodiment, referring to FIG. 2, the morphology of the opening area 10b11 is the same as a morphology of the sub-opening 15. In one example, the morphology may be understood as a shape. This is equivalent to forming an opening in all the area of the opening area 10b11, and an opening area can be made large enough to increase the light transmittance, and the number of sub-openings 15 can be reduced, thereby lowering manufacturing costs of the sub-openings 15.

In one embodiment, the pixel area 10b12 is provided with a plurality of pixel units 12, and a morphology of the opening area 10b11 is the same as a morphology of a pixel unit area corresponding to one of the pixel units 12. In one embodiment, as shown in FIG. 2, the morphology of the opening area 10b11 is the same as a morphology of a pixel unit area corresponding to a pixel unit 12 located below the opening area 10b11. In one embodiment, other pixel units 12 in the pixel area 10b12 may, in one embodiment, be considered to be obtained by rotating the pixel unit 12 by a specific angle.

In one embodiment, referring to FIG. 5, the first region 10b1 includes a plurality of opening areas 10b11. This is conducive to increasing an opening area, thereby increasing a light transmittance.

In one embodiment, the opening areas 10b11 in the same first region 10b1 have a same shape; or the opening areas 10b11 in the same first region 10b1 have different shapes. In this way, during opening formation, it is convenient for process engineers to provide the opening areas 10b11 according to actual requirements, thereby reducing the arrangement difficulty and the configuration difficulty of the opening areas 10b11.

In one embodiment, referring to FIG. 5, a sub-pixel 121 is further disposed between two adjacent first regions 10b1, and the sub-pixel 121 may include at least one of the first sub-pixel 121a, the second sub-pixel 121b, or the third sub-pixel 121c.

In one embodiment, at least one pixel unit 12 is further disposed between two adjacent first regions 10b1. In this way, a number of pixel units 12 in the light-transmitting active area 10b may be increased, thereby improving the display performance in the light-transmitting active area 10b.

In one embodiment, the pixel unit 12 includes one first sub-pixel 121a, one second sub-pixel 121b, and one third sub-pixel 121c, and centroids of the first sub-pixel 121a, the second sub-pixel 121b, and the third sub-pixel 121c in the same pixel unit 12 are connected to form a triangle. In this way, the sub-pixels 121 in the pixel area 10b12 form one pixel unit 12 (RGB unit) for light emission, thereby ensuring the display effects in the first regions 10b1.

In one embodiment, the shape of the opening area 10b11 is triangular. In this way, the shape of the opening area 10b11 may better match arrangement of the pixel unit 12, which is conducive to maximizing the size of the opening area 10b11, thereby increasing the light transmittance. It should be noted that due to manufacturing process constraints, the opening area 10b11 herein may be approximately triangular or have a shape similar to a triangle.

In one embodiment, referring to FIG. 11, the shape of the opening area 10b11 is T-shaped. In this way, the three sub-pixels 121 of the pixel unit 12 are arranged in a T-shape, and such arrangement allows the shape of the opening area 10b11 to better match the arrangement of the pixel unit 12, which is conducive to maximizing the size of the opening area 10b11, thereby increasing the light transmittance. It should be noted that due to manufacturing process constraints, the shape of the opening area 10b11 herein may be approximately T-shaped or has a shape similar to a T-shape.

In one embodiment, the first sub-pixel 121a is used to emit blue light; the second sub-pixel 121b is used to emit green light; and the third sub-pixel 121c is used to emit red light.

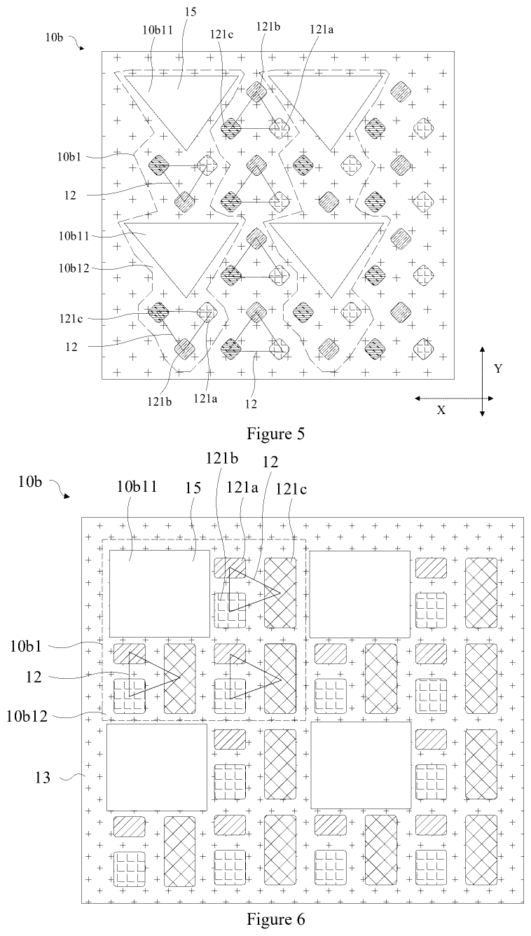

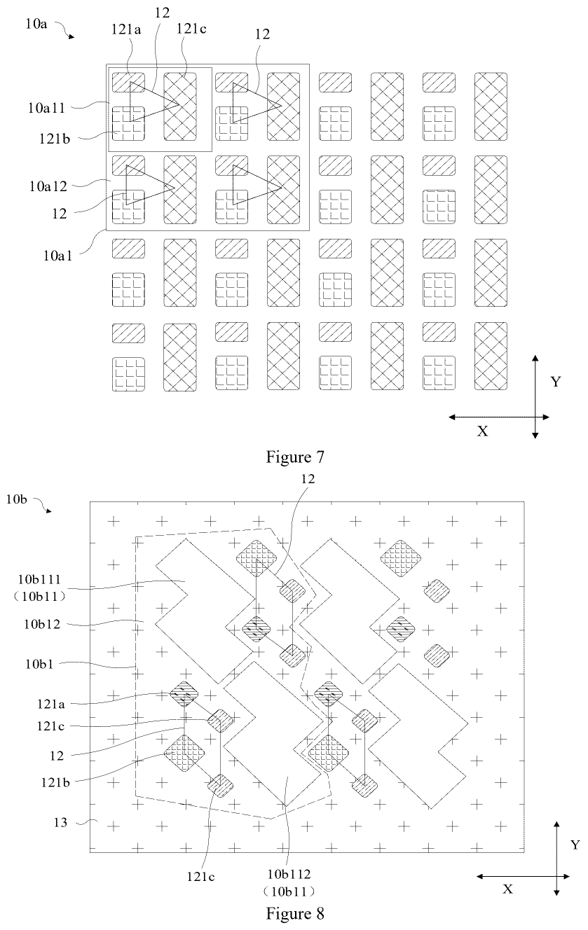

In one embodiment, referring to FIG. 6 and FIG. 7, the pixel unit 12 includes one first sub-pixel 121a, one second sub-pixel 121b, and one third sub-pixel 121c. In the same pixel unit 12, the first sub-pixel 121a and the second sub-pixel 121b are arranged along a column direction, the third sub-pixel 121c is located on a side of the first sub-pixel 121a and the second sub-pixel 121b, and along a row direction, an orthographic projection of the third sub-pixel 121c on a plane perpendicular to the row direction overlaps with an orthographic projection of the first sub-pixel 121a on the plane perpendicular to the row direction; and the orthographic projection of the third sub-pixel 121c on the plane perpendicular to the row direction overlaps with an orthographic projection of the second sub-pixel 121b on the plane perpendicular to the row direction. This is conducive to improving an aperture ratio, thereby enhancing the display effect.

In one embodiment, a distance between a side of the first sub-pixel 121a away from the second sub-pixel 121b and a side of the second sub-pixel 121b away from the first sub-pixel 121a is equal to a length of the third sub-pixel 121c in the column direction. This is conducive to the full utilization of space in the column direction of the pixel unit 12, which is conducive to improving the aperture ratio, thereby enhancing the display effect.

In one embodiment, the shape of the opening area 10b11 is rectangular. For example, the shape of the opening area 10b11 may be square or rectangular.

In one embodiment, the first sub-pixel 121a is used to emit red light; the second sub-pixel 121b is used to emit green light; and the third sub-pixel 121c is used to emit blue light.

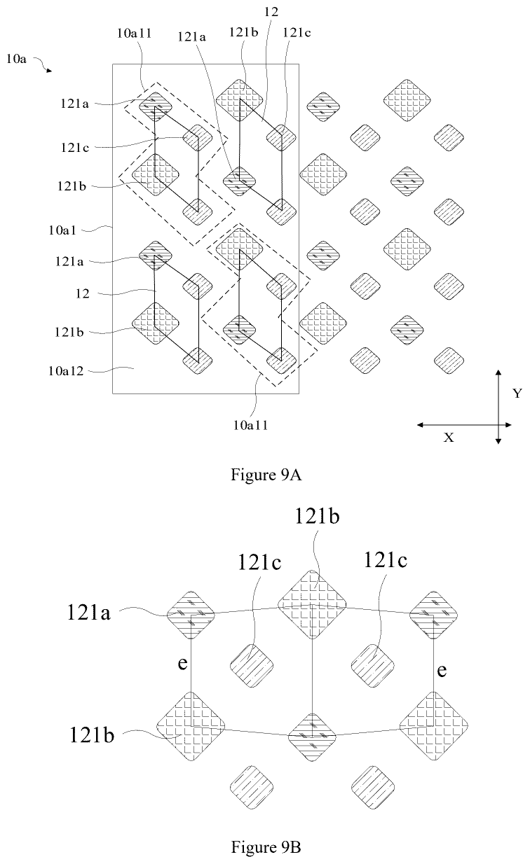

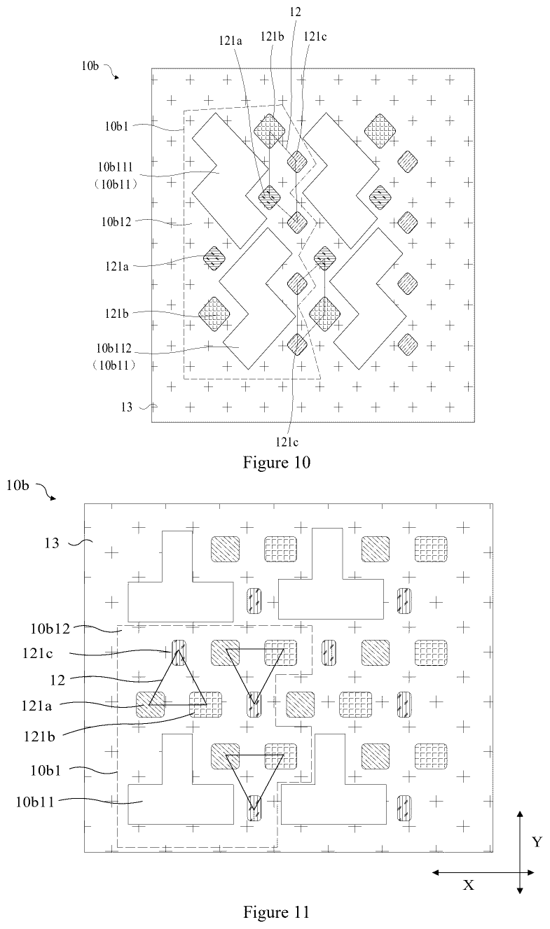

In one embodiment, referring to FIG. 8, FIG. 9A, and FIG. 10, the pixel unit 12 includes one first sub-pixel 121a, one second sub-pixel 121b, and two third sub-pixels 121c, where the first sub-pixel 121a and the second sub-pixel 121b are arranged along a first column, and the two third sub-pixels 121c are arranged along a second column. That is, the first sub-pixel 121a and the second sub-pixel 121b are arranged in the first column along a second direction Y, and the two third sub-pixels 121c are arranged in the second column along the second direction Y, with the second column being located on the right side of the first column. Centroids of the first sub-pixel 121a, the second sub-pixel 121b, and the third sub-pixels 121c in one pixel unit 12 form a quadrilateral.

In this way, the sub-pixels 121 in the pixel area 10b12 form one pixel unit 12 (RGB unit) for light emission, thereby ensuring the display effects in the first regions 10b1.

In one embodiment, the first sub-pixel 121a and the third sub-pixel 121c are not in a same row, and the second sub-pixel 121b and the third sub-pixel 121c are not in a same row. In one embodiment, the first sub-pixel 121a and the second sub-pixel 121b are located in odd-numbered rows, and the two third sub-pixels 121c are respectively located in even-numbered rows. This is equivalent to misaligning the third sub-pixel 121c with the first sub-pixel 121a, and misaligning the third sub-pixel 121c with the second sub-pixel 121b. This is conducive to mixing of light of the sub-pixels 121 having three colors, thereby improving the display effect.

In one embodiment, the first sub-pixel 121a is used to emit red light; the second sub-pixel 121b is used to emit blue light; and the third sub-pixel 121c is used to emit green light.

In one embodiment, the shape of the opening area 10b11 is Z-shaped. The above arrangement allows the shape of the opening area 10b11 to better match the arrangement of the pixel unit 12, which is conducive to maximizing the size of the opening area 10b11, thereby increasing the light transmittance.

It should be noted that due to manufacturing process constraints, the shape of the opening area 10b11 herein may be approximately Z-shaped or have a shape similar to a Z-shape.

In one embodiment, the display panel 10 further includes at least one active area 10a located on a side of the light-transmitting active area 10b, the active area 10a includes a plurality of second regions 10al arranged in an array; each of the second regions 10al includes a plurality of sub-pixels 121, the plurality of sub-pixels 121 including a plurality of first sub-pixels 121a, a plurality of second sub-pixels 121b, and a plurality of third sub-pixels 121c; the second region 10al includes at least one first sub-region 10a11 and at least one second sub-region 10a12, the second sub-region 10a12 including at least one first sub-pixel 121a, at least one second sub-pixel 121b, and at least one third sub-pixel 121c; the first regions 10b1 located in the light-transmitting active area 10b correspond to the second regions 10al located in the active area 10a; and the opening area 10b11 corresponds to the first sub-region 10a11, the pixel area 10b12 corresponds to the second sub-region 10a12, and an arrangement rule of sub-pixels 121 in the pixel area 10b12 is the same as an arrangement rule of pixels in the second sub-region 10a12, which is conducive to improving the display effect.

It can be understood that the light transmittance of the light-transmitting active area 10b is greater than the light transmittance of the active area 10a. For example, the active area 10a may be disposed around an outer contour of the light-transmitting active area 10b.

Here, through comparison between FIG. 2 and FIG. 4, it can be seen that a difference between pixel arrangement of the second region 10al and pixel arrangement of the first region 10b1 lies in the opening area 10b11 and the first sub-region 10a11. Assuming that a conventional display panel 10 (a display panel 10 without the opening area 10b11) includes a plurality of second regions 10al arranged in an array, this embodiment of the present application is equivalent to removing the sub-pixels 121 in the first sub-regions 10a11 of the second regions 10al located in the light-transmitting active area 10b. This helps to increase the light transmittance of the light-transmitting active area 10b.

It should be noted that the arrangement rule of the sub-pixels 121 in the pixel area 10b12 may also be different from the arrangement rule of the pixels in the second sub-region 10a12. This configuration is not limited in the embodiments of the present application.

In one embodiment, the first sub-region 10a11 includes at least one first sub-pixel 121a, at least one second sub-pixel 121b, and at least one third sub-pixel 121c. In this way, it can be considered that at least one first sub-pixel 121a, at least one second sub-pixel 121b, and at least one third sub-pixel 121c in an area where the opening area 10b11 is located are removed, that is, when finally forming sub-pixels 121, corresponding sub-pixels 121 for light emission are not formed in this area, and the size of the opening area 10b11 can be made relatively large, thereby increasing the light transmittance.

In one embodiment, the pixel area 10b12 includes at least one pixel unit 12, where the pixel unit 12 includes one first sub-pixel 121a, one second sub-pixel 121b, and one third sub-pixel 121c, or the pixel unit 12 includes one first sub-pixel 121a, one second sub-pixel 121b, and two third sub-pixels 121c.

It should be noted that the pixel unit 12 in the embodiments of the present application is used to emit colored light, and is formed by a red sub-pixel, a green sub-pixel, and a blue sub-pixel together. In this way, the sub-pixels 121 in the pixel area 10b12 form one pixel unit 12 (RGB unit) for light emission, thereby ensuring the display effect.

In one embodiment, the first sub-region 10a11 includes at least one pixel unit 12. In this way, it can be considered that at least one pixel unit 12 in an area where the opening area 10b11 is located is removed, and the size of the opening area 10b11 can be made relatively large, thereby increasing the light transmittance.

In one embodiment, a plurality of the second regions 10al are arranged along a first direction X. In this way, more regular arrangement of the second regions 10al can be achieved, thereby ensuring the display effect.

In one embodiment, a plurality of the second regions 10al are arranged along a second direction Y, and the second direction Y intersects with the first direction X. In this way, more regular arrangement of the second regions 10al can be achieved, thereby ensuring the display effect. In one embodiment, the second direction Y is perpendicular to the first direction X.

In one embodiment, a plurality of the first regions 10b1 are arranged along the first direction X and/or the second direction Y. In this way, more regular arrangement of the first regions 10b1 can be achieved, and the arrangement rule of the first regions 10b1 can be made the same as the arrangement rule of the second regions 10a1, thereby ensuring the display effect.

In one embodiment, among a plurality of the first regions 10b1, opening areas 10b11 in any two of the first regions 10b1 have same relative positions in the corresponding first regions 10b1. This is equivalent to making configuration positions of the opening areas 10b11 in the first regions 10b1 the same. This is conducive to more regular arrangement of the opening areas 10b11, and is conducive to reducing the opening formation difficulty.

In one embodiment, opening areas 10b11 in at least two of the first regions 10b1 have different relative positions in the corresponding first regions 10b1. This is equivalent to making configuration positions of opening areas 10b11 in at least two first regions 10b1 different, which helps designers to adjust positions of the opening areas 10b11 according to actual requirements, thereby facilitating fulfillment of different opening formation requirements.

In one embodiment, the second region 10al includes a plurality of pixel units 12, where a part of the sub-pixels 121 in the first sub-region 10a11 corresponding to the opening area 10b11 is a part of one pixel unit 12, and another part of the sub-pixels 121 in the first sub-region 10a11 is a part of another pixel unit 12.

This is equivalent to removing a part of one pixel unit 12 and a part of another pixel unit 12. That is, the removed sub-pixels 121 do not constitute one or several complete pixel units 12. This helps designers to adjust positions of the opening areas 10b11 according to actual requirements, thereby facilitating fulfillment of different opening formation requirements.

In one embodiment, as shown in FIG. 2 and FIG. 6, the first region 10b1 includes one opening area 10b11. In this way, a number of opening areas 10b11 in the first region 10b1 can be minimized, thereby improving the display effect of the light-transmitting active area 10b.

In one embodiment, the pixel area 10b12 includes a plurality of pixel units 12, where the pixel unit 12 includes one first sub-pixel 121a, one second sub-pixel 121b, and one third sub-pixel 121c. This is conducive to improving an aperture ratio of the first region 10b1, thereby enhancing the display effect.

In one embodiment, the pixel area 10b12 includes three pixel units 12. This can improve the display effect of the light-transmitting active area 10b to the greatest extent.

In one embodiment, the first sub-region 10a11 corresponding to the opening area 10b11 includes one pixel unit 12; and the second sub-region 10a12 includes three pixel units 12. This is equivalent to removing one pixel unit 12 in the first region 10b1, while retaining three pixel units 12 in the pixel area 10b12. This can improve the display effect of the light-transmitting active area 10b to the greatest extent, while ensuring the light transmittance of the light-transmitting active area 10b.

In one embodiment, as shown in FIG. 2, among the three pixel units 12 in the pixel area 10b12, one pixel unit 12 (the pixel unit 12 located at an upper right corner) is located on a side of the opening area 10b11 along the first direction X, another pixel unit 12 (the pixel unit 12 located at a lower left corner) is located on a side of the opening area 10b11 along the second direction Y, and still another pixel unit 12 (the pixel unit 12 located at a lower right corner) is located on a side of the pixel unit 12 (the pixel unit 12 located at the upper right corner) along the second direction Y, and on a side of the another pixel unit 12 (the pixel unit 12 located at the lower left corner) along the first direction X, where the first direction X intersects with the second direction Y.

This can improve the display effect of the light-transmitting active area 10b to the greatest extent, while ensuring the light transmittance of the light-transmitting active area 10b; and this enables two opening areas 10b11 adjacent along the first direction X to be relatively close, which is conducive to improving the light transmission effect.

In one embodiment, centroids of the first sub-pixel 121a, the second sub-pixel 121b, and the third sub-pixel 121c in the same pixel unit 12 are connected to form a triangle. In this way, the sub-pixels 121 in the pixel area 10b12 form one pixel unit 12 (RGB unit) for light emission, thereby ensuring the display effects in the first regions 10b1.

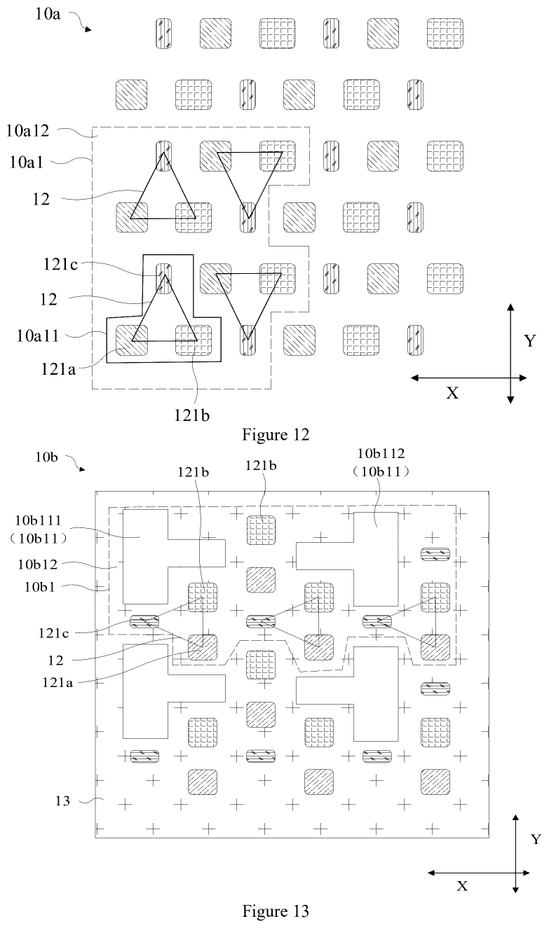

In one embodiment, referring to FIG. 11 and FIG. 12, along a first direction X, the first sub-pixel 121a, the second sub-pixel 121b, and the third sub-pixel 121c are sequentially arranged; and along a second direction Y, a plurality of the first sub-pixels 121a are sequentially arranged, a plurality of the second sub-pixels 121b are sequentially arranged, and a plurality of the third sub-pixels 121c are sequentially arranged.

In one embodiment, the shape of the opening area 10b11 may be triangular. In this way, the shape of the opening area 10b11 may better match arrangement of the pixel unit 12, which is conducive to maximizing the size of the opening area 10b11, thereby increasing the light transmittance. It should be noted that due to manufacturing process constraints, the shape of the opening area 10b11 herein may be approximately triangular or has a shape similar to a triangle.

In one embodiment, the shape of the opening area 10b11 may be T-shaped. In this way, the three sub-pixels 121 of the pixel unit 12 are arranged in a T-shape, and such arrangement allows the shape of the opening area 10b11 to better match the arrangement of the pixel unit 12, which is conducive to maximizing the size of the opening area 10b11, thereby increasing the light transmittance. It should be noted that due to manufacturing process constraints, the shape of the opening area 10b11 herein may be approximately T-shaped or has a shape similar to a T-shape.

In one embodiment, the first sub-pixel 121a is used to emit blue light; the second sub-pixel 121b is used to emit green light; and the third sub-pixel 121c is used to emit red light.

In one embodiment, in two adjacent first regions 10b1 along the first direction X, opening areas 10b11 of the two first regions 10b1 are adjacent to each other. This is conducive to concentrating the opening areas 10b11, thereby further increasing the light transmittance.

In one embodiment, referring to FIG. 6 and FIG. 7, along a second direction Y, the first sub-pixel 121a and the second sub-pixel 121b are sequentially arranged, and the third sub-pixel 121c is sequentially arranged, and in the same pixel unit 12, along the first direction X, an orthographic projection of the third sub-pixel 121c on a plane perpendicular to the first direction X overlaps with an orthographic projection of the first sub-pixel 121a on the plane perpendicular to the first direction X, and the orthographic projection of the third sub-pixel 121c on the plane perpendicular to the first direction X overlaps with an orthographic projection of the second sub-pixel 121b on the plane perpendicular to the first direction X. This is conducive to improving the aperture ratio, thereby enhancing the display effect.

In one embodiment, in a same pixel unit 12, a distance between a side of the first sub-pixel 121a away from the second sub-pixel 121b and a side of the second sub-pixel 121b away from the first sub-pixel 121a is equal to a length of the third sub-pixel 121c in the second direction Y. This is conducive to the full utilization of space in the column direction of the pixel unit 12, which is conducive to improving the aperture ratio, thereby enhancing the display effect.

In one embodiment, the shape of the opening area 10b11 is rectangular. For example, the shape of the opening area 10b11 may be square or rectangular.

In one embodiment, the first sub-pixel 121a is used to emit red light; the second sub-pixel 121b is used to emit green light; and the third sub-pixel 121c is used to emit blue light.

In one embodiment, the pixel area 10b12 includes at least one pixel unit 12, where the pixel unit 12 includes one first sub-pixel 121a, one second sub-pixel 121b, and two third sub-pixels 121c. This helps to improve the display effect of the light-transmitting active area 10b.

In one embodiment, the first sub-region 10a11 corresponding to the opening area 10b11 includes at least one pixel unit 12. In this way, it can be considered that at least one pixel unit 12 in an area where the opening area 10b11 is located is removed, and the size of the opening area 10b11 can be made relatively large, thereby increasing the light transmittance.

In one embodiment, referring to FIG. 9A and FIG. 9B, the second region 10al includes a plurality of pixel units 12; two first sub-pixels 121a are located at two first vertices of a first virtual quadrilateral e, and two second sub-pixels 121b are located at two second vertices of the first virtual quadrilateral e; the two first vertices and the two second vertices are disposed alternately and spaced apart from each other; and the third sub-pixel 121c is located within the first virtual quadrilateral e. This is equivalent to arranging the sub-pixels 121 in the second region 10al in a tripod-shaped pixel arrangement pattern. For specific pixel arrangement, reference may be made to Patent CN112802884A.

In one embodiment, the first virtual quadrilateral is an isosceles trapezoid.

In one embodiment, the first sub-pixel 121a is used to emit red light; the second sub-pixel 121b is used to emit blue light; and the third sub-pixel 121c is used to emit green light.

In one embodiment, the pixel area 10b12 includes a plurality of pixel units 12. This is conducive to improving the aperture ratio, thereby enhancing the display effect.

In one embodiment, the shape of the opening area 10b11 is Z-shaped. It should be noted that due to manufacturing process constraints, the shape of the opening area 10b11 herein may be approximately Z-shaped or has a shape similar to a Z-shape.

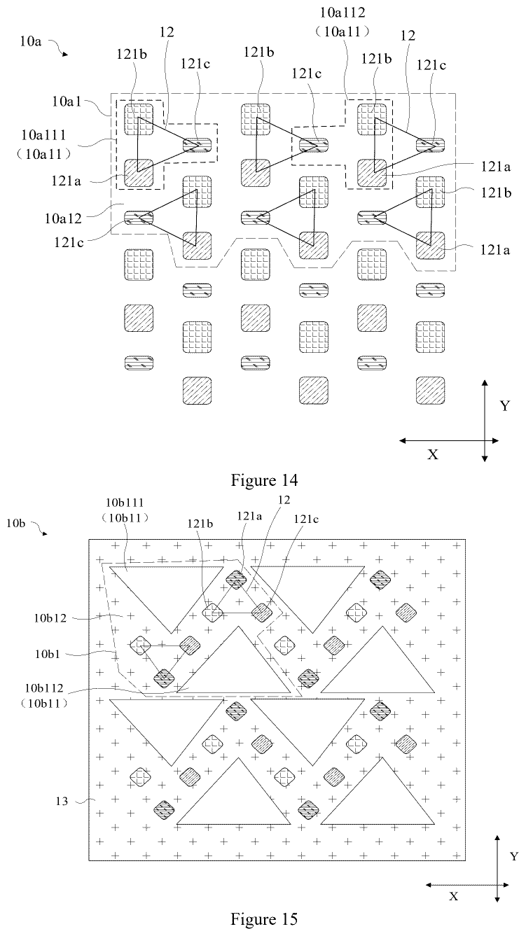

In one embodiment, referring to FIG. 13 and FIG. 14, the first region 10b1 includes a plurality of opening areas 10b11. This is conducive to increasing an opening area in the first region 10b1, thereby increasing the light transmittance. For example, the number of opening areas 10b11 may be 1, 2, 3, or a larger value.

Further, the second region 10al includes a plurality of first sub-regions 10a11, the second region 10al includes a plurality of pixel units 12, and the pixel unit 12 includes one first sub-pixel 121a, one second sub-pixel 121b, and one third sub-pixel 121c; or the pixel unit 12 includes one first sub-pixel 121a, one second sub-pixel 121b, and two third sub-pixels 121c. It should be noted that the pixel unit 12 in the embodiments of the present application is used to emit colored light, and is formed by a red sub-pixel 121, a green sub-pixel 121, and a blue sub-pixel 121 together. In this way, the sub-pixels 121 in the second region 10al form one pixel unit 12 (RGB unit) for light emission, thereby ensuring the display effects in the first regions 10b1.

Further, as shown in FIG. 14, a part of sub-pixels 121 in at least one of the first sub-regions 10a11 (the first sub-region 10a11 located on the right side) is a part of one pixel unit 12, and another part of the sub-pixels 121 in the first sub-region 10a11 is a part of another pixel unit 12.

In one embodiment, referring to FIG. 13, the plurality of opening areas 10b11 include at least one first sub-opening area 10b111 and at least one second sub-opening area 10b112; and the at least one first sub-opening area 10b111 and/or the at least one second sub-opening area 10b112 is adjacent to the pixel area 10b12. This is conducive to achieving more uniform arrangement of the opening areas 10b11 and the pixel area 10b12 in the first region 10b1, thereby enhancing the display effect while increasing the light transmittance.

In one embodiment, the plurality of first sub-regions 10a11 include at least one sub-region I 10a111 and at least one sub-region II 10a112, where the sub-region I 10a111 corresponds to the first sub-opening area 10b111, and the sub-region II 10a112 corresponds to the second sub-opening area 10b112.

This is equivalent to, when removing the sub-pixels 121, removing the sub-pixels 121 corresponding to the sub-region I 10a111 and the sub-region II 10a112. This provides more manners for removing the sub-pixels 121 in the second region 10al, and process operators make selections according to actual requirements.

In one embodiment, a part of sub-pixels 121 in at least one of the first sub-regions 10a11 that corresponds to one opening area 10b11 is a part of one pixel unit 12, and another part of the sub-pixels 121 in the first sub-region 10a11 is a part of another pixel unit 12. With reference to FIG. 13 and FIG. 14, a part of sub-pixels 121 in the sub-region II 10a112 corresponding to the second sub-opening area 10b112 is a part of one pixel unit 12, and another part of the sub-pixels 121 in the sub-region II 10a112 is a part of another pixel unit 12.

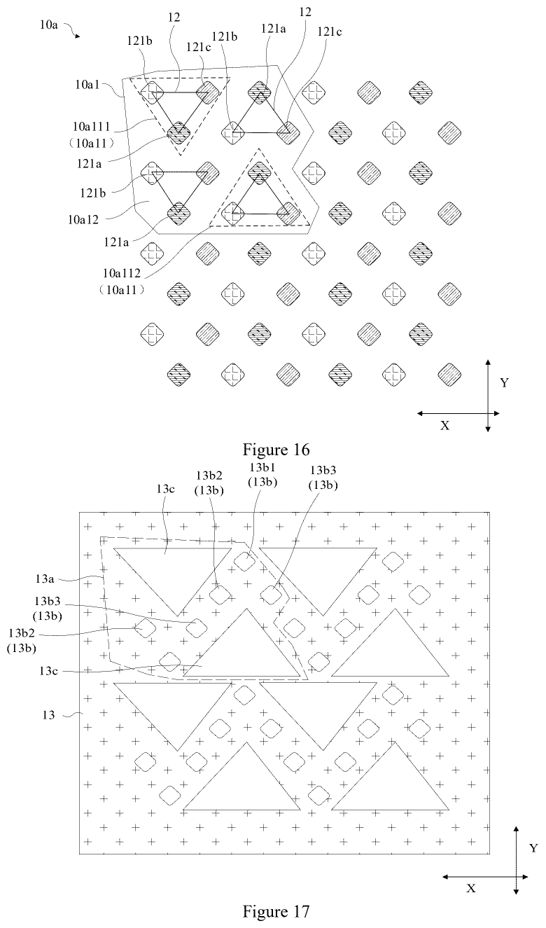

In one embodiment, referring to FIG. 15, FIG. 16, and FIG. 17, the pixel area 10b12 includes a plurality of pixel units 12, and the first sub-opening area 10b111 and the second sub-opening area 10b112 are both adjacent to the corresponding pixel area 10b12. This is conducive to achieving more uniform arrangement of the opening areas 10b11 and the pixel area 10b12 in the first region 10b1, thereby enhancing the display effect while increasing the light transmittance.

In one embodiment, the plurality of opening areas 10b11 include one first sub-opening area 10b111 and one second sub-opening area 10b112. This provides diversified opening formation manners in the first region 10b1, and process operators perform opening formation operations in the first region 10b1 according to actual requirements.

In one embodiment, the sub-region I 10a111 corresponding to the first sub-opening area 10b111 includes one pixel unit 12, and the sub-region II 10a112 corresponding to the second sub-opening area 10b112 includes one pixel unit 12. This is equivalent to removing a complete pixel unit 12. In this way, the size of the opening area 10b11 may be made large enough, thereby increasing the light transmittance; and compared with the manner of removing a part of the sub-pixels 121 in the pixel unit 12, removing a complete pixel unit 12 can prevent a part of the sub-pixels 121 in the pixel unit 12 from being retained, thereby avoiding color cast or chromatic aberration during light emission.

In one embodiment, the pixel area 10b12 includes two pixel units 12. This is conducive to improving an aperture ratio of the first region 10b1, thereby enhancing the display effect.

In one embodiment, as shown in FIG. 15, in the two pixel units 12 in the pixel area 10b12, one of the pixel units 12 (the pixel unit 12 at an upper right corner) is located on a side of the first sub-opening area 10b111 along a first direction X, and the second sub-opening area 10b112 is located on a side of the pixel unit 12 (the pixel unit 12 at the upper right corner) along a second direction Y; and the other pixel unit 12 (a pixel unit 12 at a lower left corner) is located on a side of the first sub-opening area 10b111 along the second direction Y, and the second sub-opening area 10b112 is located on a side of the other pixel unit 12 along the first direction X. This can enable more uniform arrangement of the pixel units 12 and the opening areas 10b11 in the first region 10b1, which can improve the display effect of the light-transmitting active area 10b to the greatest extent, while ensuring the light transmittance of the light-transmitting active area 10b.

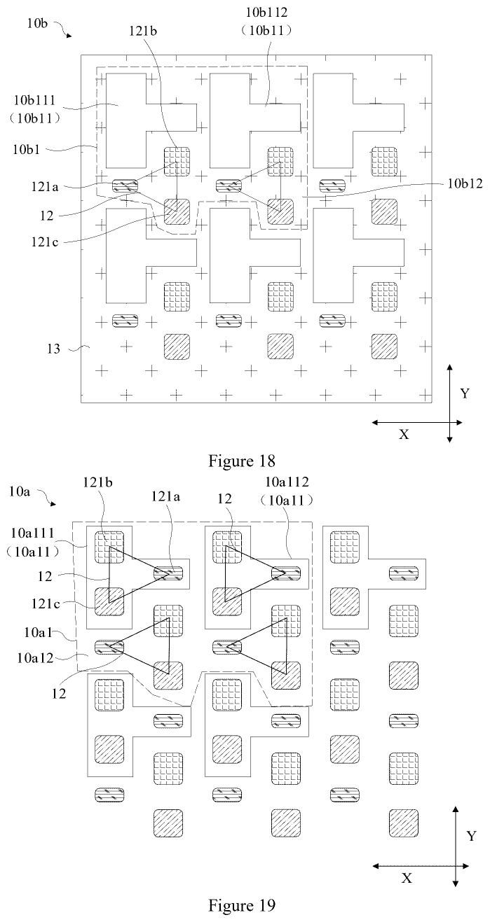

In one embodiment, referring to FIG. 18 and FIG. 19, the two pixel units 12 are adjacent along the first direction X, and the first sub-opening area 10b111 and the second sub-opening area 10b112 are adjacent along the first direction X. This is conducive to concentrating the opening areas 10b11, thereby further increasing the light transmittance.

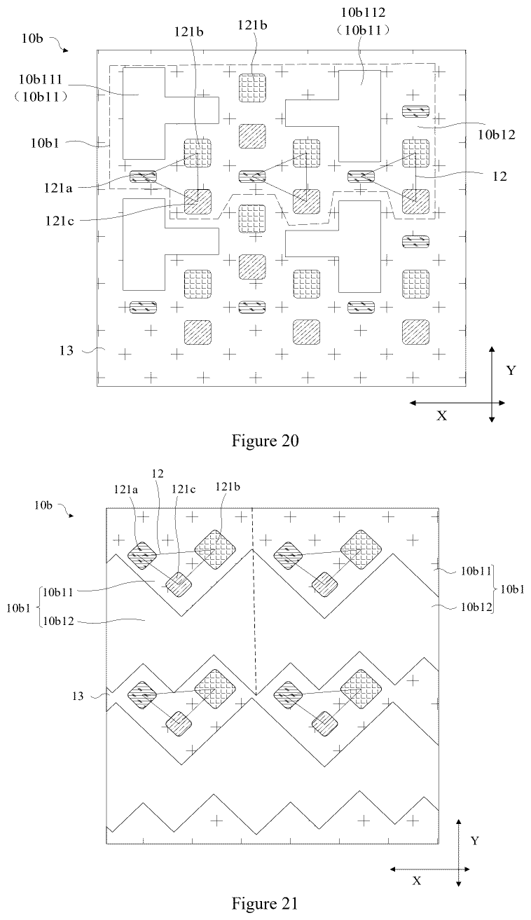

In one embodiment, referring to FIG. 20, the pixel area 10b12 includes four pixel units 12.

In one embodiment, three pixel units 12 in the pixel area 10b12 are sequentially arranged along the first direction X, the first sub-opening area 10b111 and the second sub-opening area 10b112 are spaced apart along the first direction X, and the first sub-opening area 10b111 and the second sub-opening area 10b112 are located on a side of the three pixel units 12 along the second direction Y. The second sub-pixel 121b and the third sub-pixel 121c of another pixel unit 12 are located between the first sub-opening area 10b111 and the second sub-opening area 10b112, and the first sub-pixel 121a of another pixel unit 12 is located on a side of the second sub-opening area 10b112 away from the first sub-opening area 10b111.

In one embodiment, referring to FIG. 17, the shapes of the first sub-opening area 10b111 and the second sub-opening area 10b112 are each triangular.

In one embodiment, referring to FIG. 10, the shapes of the first sub-opening area 10b111 and the second sub-opening area 10b112 are each Z-shaped.

In one embodiment, referring to FIG. 20, the shapes of the first sub-opening area 10b111 and the second sub-opening area 10b112 are each T-shaped.

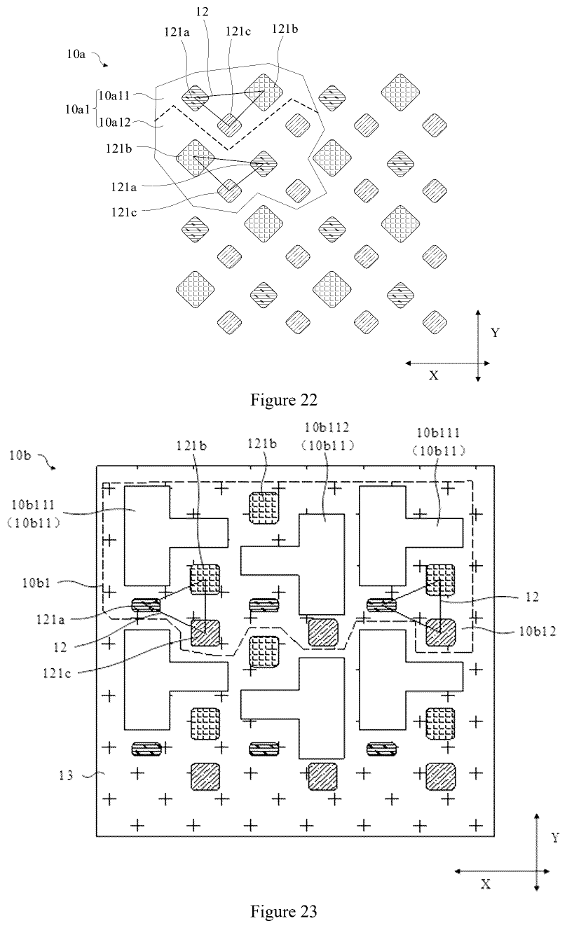

In one embodiment, with reference to FIG. 21 and FIG. 22, in two adjacent first regions 10b1 along the first direction X, the opening areas 10b11 of the two first regions 10b1 are adjacent to each other, and the pixel areas 10b12 of the two first regions 10b1 are adjacent to each other. This enables a size of the opening area 10b11 to be maximized, thereby maximizing the light transmittance of the light-transmitting active area 10b.

In one embodiment, referring to FIG. 23, the first region 10b1 includes a plurality of opening areas 10b11. The plurality of opening areas 10b11 include a plurality of first sub-opening areas 10b111 and at least one second sub-opening area 10b112; and one second sub-opening area 10b112 is disposed between two adjacent first sub-opening areas 10b111. This is conducive to increasing an opening area in the first region 10b1, thereby increasing the light transmittance.

In one embodiment, the plurality of opening areas 10b11 include two first sub-opening areas 10b111 and one second sub-opening area 10b112. Further, the pixel area 10b12 includes two pixel units 12. This can minimize impact on the display effect to the greatest extent while increasing the opening area.

In one embodiment, the two first sub-opening areas 10b111 and the second sub-opening area 10b112 are sequentially arranged along the first direction X, the two pixel units 12 in the pixel area 10b12 are in one-to-one correspondence with the two first sub-opening areas 10b111, and each pixel unit 12 is located on a side of the corresponding first sub-opening area 10b111 along the first direction X. This can minimize impact on the display effect to the greatest extent while increasing the opening area.

In one embodiment, one first sub-pixel 121a and one third sub-pixel 121c are disposed on a side of the second sub-opening area 10b112 along the second direction Y, and at least one second sub-pixel 121b is disposed on the other side of the second sub-opening area 10b112 along the second direction Y. In one embodiment, the shapes of the first sub-opening area 10b111 and the second sub-opening area 10b112 are T-shaped. In one embodiment, orientations of the two first sub-opening areas 10b111 are the same, and an orientation of the second sub-opening area 10b112 is opposite to an orientation of the first sub-opening area 10b111.

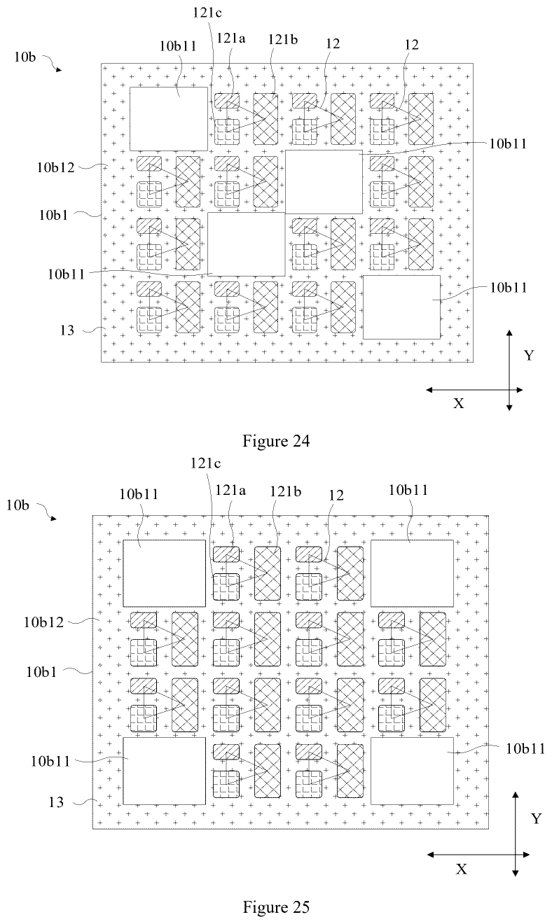

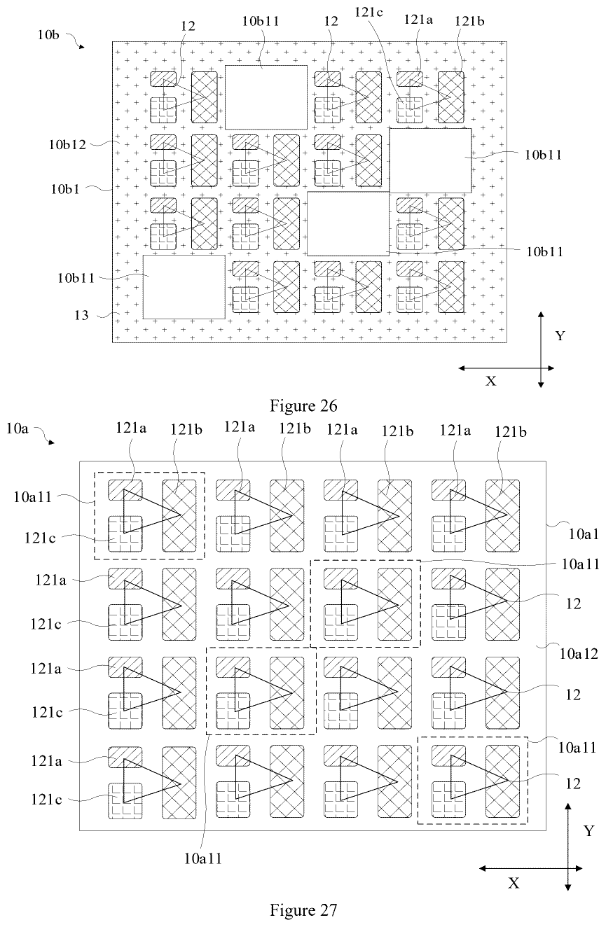

In one embodiment, referring to FIG. 24, FIG. 25, and FIG. 26, the pixel area 10b12 includes a plurality of pixel units 12, the first region 10b1 includes a plurality of opening areas 10b11, and the pixel unit 12 is arranged on at least one side of the opening area 10b11 along the first direction X, and/or the pixel unit 12 is arranged on at least one side of the opening area 10b11 along the second direction Y. In this way, a number of pixel units 12 in the pixel area 10b12 may be increased, thereby improving the display effect.

In one embodiment, with reference to FIG. 24 and FIG. 27, the first sub-region 10a11 corresponding to the opening area 10b11 includes one pixel unit 12, that is, the opening area 10b11 includes one pixel unit 12. In this way, the size of the opening area 10b11 may be made large enough, thereby increasing the light transmittance; and compared with the manner of removing a part of the sub-pixels 121 in the pixel unit 12, removing a complete pixel unit 12 can prevent a part of the sub-pixels 121 in the pixel unit 12 from being retained, thereby avoiding color cast or chromatic aberration during light emission.

In one embodiment, the second region 10al corresponding to the first region 10b1 includes a plurality of pixel units 12, the plurality of pixel units 12 being arranged in rows along the first direction X and arranged in columns along the second direction Y. In this way, more regular arrangement of the pixel units 12 can be achieved, thereby improving the display effect.

In one embodiment, the number of opening areas 10b11 in the first region 10bl is n, and the number of pixel units 12 in the second region 10al corresponding to the first region 10b1 is n². In one example, the number of opening areas 10b11 is 2, and the number of pixel units 12 in the second region 10al is 4. In another example, the number of opening areas 10b11 is 4, and the number of pixel units 12 in the second region 10al is 16.

In one embodiment, in the first region 10b1, each pixel unit row is provided with one opening area 10b11. This is equivalent to positioning one pixel unit 12 in each pixel unit row in the opening area 10b11. This provides more manners for removing the pixel units 12 in the second region 10al, and process operators make selections according to actual requirements.

In one embodiment, in the first region 10b1, each pixel unit column is provided with one opening area 10b11. This is equivalent to positioning one pixel unit 12 in each pixel unit column in the opening area 10b11. This provides more manners for removing the pixel units 12 in the second region 10al, and process operators make selections according to actual requirements.

In one embodiment, in the first region 10b1, among all pixel unit rows in the same first region 10b1, two opening areas 10b11 are respectively provided in outermost pixel unit rows; and among all pixel unit columns in the same first region 10b1, two opening areas 10b11 are respectively provided in outermost pixel unit columns. That is, four opening areas 10b11 are located at four corners of the second region 10a1. In this way, a part of the opening areas 10b11 in adjacent first regions 10b1 are arranged adjacent to each other, which is conducive to achieving more uniform arrangements of the opening areas 10b11 and the pixel units 12 in the light-transmitting active area 10b. In this way, the display effect of the light-transmitting active area 10b can be ensured to the greatest extent, while increasing the light transmittance of the light-transmitting active area 10b.

In one embodiment, the shapes of the opening areas 10b11 are all rectangular. Referring to FIG. 27, areas where three sub-pixels 121 of the pixel unit 12 are located are rectangular. Such arrangement allows the shape of the opening area 10b11 to better match the arrangement of the pixel unit 12, which is conducive to maximizing the size of the opening area 10b11, thereby increasing the light transmittance.

It should be noted that due to manufacturing process constraints, the shape of the opening area 10b11 herein may be approximately rectangular or has a shape similar to a rectangle.

In one embodiment, the display panel 10 includes a plurality of pixel groups arranged repeatedly; the pixel group includes at least one first sub-pixel 121a, at least one second sub-pixel 121b, and at least one third sub-pixel 121c; and the second region 10al includes at least one pixel group. Here, the pixel group refers to: the smallest repeating unit arranged repeatedly in an arrangement structure of the sub-pixels 121.

In one embodiment, one second region 10al may include one or more pixel groups; and certainly, one second region 10al may also include 1.5, 2.5, or 4.5 pixel groups.

In one embodiment, the second region 10al includes a plurality of pixel groups; and the first sub-region 10a11 corresponding to the opening area 10b11 includes at least one pixel group. In one embodiment, the first sub-region 10a11 corresponding to the opening area 10b11 includes one pixel group.

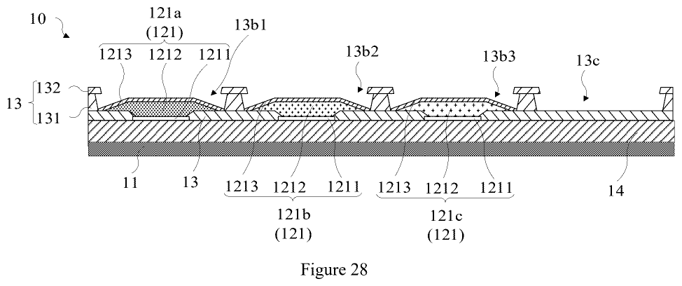

In one embodiment, referring to FIG. 28, the display panel 10 further includes an isolation structure 13. The isolation structure 13 is disposed on a side of a substrate 11, and the isolation structure 13 is provided with a plurality of isolation openings 13b and a plurality of light-transmitting openings 13c. At least part of a structure of a sub-pixel 121 is disposed in a corresponding isolation opening 13b, and the plurality of light-transmitting openings 13c are disposed in a manner corresponding to sub-openings 15 of a plurality of opening areas 10b11 of the light-transmitting active area 10b.

It should be noted that the isolation structure 13 refers to: a structure capable of isolating light-emitting materials of adjacent sub-pixels 121 during evaporation of the light-emitting materials of the sub-pixels 121. By providing the isolation structure 13, a photolithographic patterning process can be used for the sub-pixels 121, thereby eliminating the need for an FMM, which is conducive to improving PPI. Further, since the photolithographic patterning process is used to manufacture the sub-pixels 121, compared to a display panel 10 that uses the FMM for evaporating the sub-pixels 121, the isolation structure 13 may enable more diverse shapes and more optimized arrangement of the sub-pixels 121.

In one embodiment, an orthographic projection of each light-transmitting opening 13c on the substrate 11 coincides with an orthographic projection of each corresponding opening area 10b11 on the substrate 11. This increases the light transmittance to the greatest extent.

In one embodiment, an edge of the orthographic projection of the light-transmitting opening 13c on the substrate 11 may be curved or straight, which is conducive to improving the diffraction problem of a camera.

In one embodiment, a shape of the orthographic projection of the light-transmitting opening 13c on the substrate 11 may be an irregular pattern.

In one embodiment, the orthographic projection of the light-transmitting opening 13c on the substrate 11 is polygonal or circular. For example, the orthographic projection of the light-transmitting opening 13c may be triangular, rectangular, T-shaped, or Z-shaped. This is conducive to achieving matching between the light-transmitting opening 13c and an arrangement manner of a removed pixel unit 12, thereby increasing the light transmittance.

In one embodiment, the sub-pixel 121 includes a first electrode 1211, a light-emitting functional portion 1212, and a second electrode 1213 that are stacked in a direction away from the substrate 11, where the second electrode 1213 is electrically connected to the isolation structure 13. It can be understood that the isolation structure 13 may be electrically connected to a pixel circuit of the display panel 10. This embodiment of the present application is equivalent to connecting the second electrode 1213 of the sub-pixel 121 to the pixel circuit through the isolation structure 13. This enables wiring arrangement in the active area 10a to be more optimized.

In the embodiments of the present application, the first electrode 1211 is an anode, and the second electrode 1213 is a cathode. The light-emitting functional portion 1212 includes at least an emission layer (EML), and may further include one or more of a hole injection layer (HIL), a hole transport layer (HTL), an electron injection layer (EIL), an electron transport layer (ETL), a hole block layer (HBL), or an electron block layer (EBL). In one embodiment, the light-emitting functional portion 1212 may be a tandem light-emitting structure, that is, the light-emitting functional portion includes at least two emission layers and a charge generation layer (CGL) located between adjacent emission layers.

In one embodiment, the isolation structure 13 is an integrated structure, that is, isolation structures 13 corresponding to different sub-pixels are connected to form an integral structure. This facilitates signal routing through the isolation structure 13, and this can reduce the resistance of the isolation structure 13, thereby lowering power consumption.

In one embodiment, an orthographic projection of the isolation structure 13 on the substrate 11 is grid-shaped.

In one embodiment, the isolation structure 13 includes an isolation body 131 and a blocking portion 132 that are stacked in the direction away from the substrate 11, where an outer contour of an orthographic projection of the blocking portion 132 on the substrate 11 is located outside an outer contour of an orthographic projection of the isolation body 131 on the substrate 11. This enables the isolation structure 13 to form an undercut structure with a “larger upper part and smaller lower part”. During evaporation of the sub-pixels 121, this undercut structure can isolate the light-emitting materials of the sub-pixels 121.

In one embodiment, the isolation body 131 includes a conductive material, and the second electrode 1213 is electrically connected to the isolation body 131. This facilitates electrical connection between the second electrode 1213 and the isolation body 131 of the isolation structure 13, thereby connecting the second electrode 1213 of the sub-pixel 121 to the pixel circuit through the isolation body 131, which enables the wiring arrangement in the active area 10a to be more optimized.

In one embodiment, the isolation body 131 includes at least one metal layer. In one example, the isolation body 131 includes one metal layer. Further, the material of the isolation body 131 includes at least one of metal or metal oxide. For example, the metal may be silver, copper, titanium, aluminum, or the like. The metal oxide may be tin oxide, zinc oxide, cadmium oxide, indium oxide, indium tin oxide, zinc indium oxide, zinc gallium oxide, zinc aluminum oxide, titanium tantalum oxide, or the like.

In one embodiment, the isolation body 131 includes a first metal layer and a second metal layer that are stacked in a direction away from the substrate 11, where an outer contour of an orthographic projection of the first metal layer on the substrate 11 is located outside an outer contour of an orthographic projection of the second metal layer on the substrate 11. Here, the first metal layer and the second metal layer are sequentially stacked in the direction away from the substrate 11. In one example, a material of the first metal layer may be Mo, and a material of the second metal layer may be Al.

In one embodiment, a material of the blocking portion 132 includes titanium or molybdenum; the material of the first metal layer includes molybdenum or titanium; the material of the second metal layer includes aluminum or copper or silver; and in one example, a cross-sectional shape of the isolation structure 13 formed together by the first metal layer, the second metal layer, and the blocking portion 132 may be I-shaped.

In one embodiment, with reference to FIG. 15 and FIG. 17, the isolation structure 13 located in the light-transmitting active area 10b is provided with a plurality of opening groups 13a. The plurality of opening groups 13a are in one-to-one correspondence with the plurality of first regions 10b1, and each of the opening groups 13a includes a plurality of the isolation openings 13b and at least one of the light-transmitting openings 13c. The plurality of isolation openings 13b include at least one first isolation opening 13b1, at least one second isolation opening 13b2, and at least one third isolation opening 13b3. The first sub-pixel 121a corresponds to the first isolation opening 13b1, the second sub-pixel 121b corresponds to the second isolation opening 13b2, and the third sub-pixel 121c corresponds to the third isolation opening 13b3.

In one embodiment, the display panel 10 further includes an array film layer 14, the array film layer 14 being arranged between the substrate 11 and the isolation structure 13. The array film layer 14 is provided with a plurality of pixel circuits, where the plurality of pixel circuits are arranged in the active area 10a and the light-transmitting active area 10b, and the plurality of pixel circuits are electrically connected to a plurality of sub-pixels 121 correspondingly; and an orthographic projection of each pixel circuit disposed in the light-transmitting active area 10b on the substrate 11 does not overlap with an orthographic projection of each corresponding opening area 10b11 on the substrate 11; or an orthographic projection of each pixel circuit located in the light-transmitting active area 10b on the substrate 11 partially overlaps with an orthographic projection of each corresponding opening area 10b11 on the substrate 11, and the pixel circuit corresponding to an overlapping portion is configured as a transparent conductive layer.

This reduces interference of the pixel circuits to light, and increases the light transmittance of the light-transmitting active area 10b.

In one embodiment, the orthographic projection of the pixel circuit disposed in the light-transmitting active area 10b on the substrate 11 partially overlaps with the orthographic projection of the isolation structure 13 on the substrate 11.

In one embodiment, the array film layer 14 is further provided with a plurality of first signal lines, where the plurality of first signal lines are arranged in the active area 10a and the light-transmitting active area 10b, and an orthographic projection of each first signal line disposed in the light-transmitting active area 10b on the substrate 11 is located within an orthographic projection of the pixel area 10b12 on the substrate 11. This reduces interference of the first signal lines to light, and increases the light transmittance of the light-transmitting active area 10b. For example, the first signal lines may be scan lines, power lines, or the like.

In one embodiment, the array film layer 14 is further provided with a plurality of data signal lines, the plurality of data signal lines being arranged in the active area 10a and the light-transmitting active area 10b, where an orthographic projection of each data signal line disposed in the light-transmitting active area 10b on the substrate 11 partially overlaps with an orthographic projection of a corresponding opening area 10b11 on the substrate 11, and the data signal line corresponding to an overlapping portion is configured as a transparent conductive film layer. This reduces interference of the data signal lines to light, and increases the light transmittance of the light-transmitting active area 10b.

In one embodiment, the display panel 10 further includes a pixel defining layer 13, where the pixel defining layer 13 is disposed on a side of the array film layer 14 away from the substrate 11, and the isolation structure 13 is disposed on the pixel defining layer 13. The pixel defining layer 13 is provided with a plurality of pixel openings, the pixel openings being in communication with the plurality of isolation openings 13b in one-to-one correspondence.

In one embodiment, referring to FIG. 1 to FIG. 28, an embodiment of the present application provides a display panel 10 having an active area 10a and a light-transmitting active area 10b; and the display panel 10 includes a substrate 11, and an isolation structure 13 disposed on a side of the substrate 11. The isolation structure 13 is provided with a plurality of isolation openings 13b and a plurality of light-transmitting openings 13c, where the isolation openings 13b are located in the active area 10a and the light-transmitting active area 10b, and the isolation opening 13b are configured to accommodate sub-pixels 121; and the light-transmitting openings 13c are located in the light-transmitting active area 10b, and a size of each light-transmitting opening 13c is greater than a size of any one of the isolation openings 13b. Here, the size of the light-transmitting opening 13c may be considered as a size of the orthographic projection of the light-transmitting opening 13c on the substrate 11, and the size of the isolation opening 13b may be considered as a size of the orthographic projection of the isolation opening 13b on the substrate 11.

In the embodiments of the present application, the isolation openings 13b and the light-transmitting openings 13c are disposed in the light-transmitting active area 10b, where the isolation openings 13b may accommodate the sub-pixels 121, and the light-transmitting openings 13c can transmit ambient light. In this way, the light-transmitting openings 13c in the light-transmitting active area 10b help to increase the light transmittance of the light-transmitting active area 10b; and the isolation openings 13b in the light-transmitting active area 10b may accommodate the sub-pixels 121, thereby ensuring that the light-transmitting active area 10b has a specific display effect. In conclusion, the present application can ensure the display effect of the light-transmitting active area 10b, while increasing the light transmittance of the light-transmitting active area 10b.

In one embodiment, the light-transmitting active area 10b includes a plurality of first regions 10b1. The isolation structure 13 located in the first regions 10b1 is provided with a plurality of opening groups 13a, the plurality of opening groups 13a are disposed in a manner corresponding to the plurality of first regions 10b1. Each opening group 13a includes a plurality of isolation openings 13b and at least one light-transmitting opening 13c. The plurality of isolation openings 13b include at least one first isolation opening 13b1, at least one second isolation opening 13b2, and at least one third isolation opening 13b3. The first isolation opening 13b1, the second isolation opening 13b2, and the third isolation opening 13b3 are arranged in the pixel area 10b12. The display panel 10 further includes a plurality of sub-pixels 121. The plurality of sub-pixels 121 include a plurality of first sub-pixels 121a, a plurality of second sub-pixels 121b, and a plurality of third sub-pixels 121c. The first sub-pixels 121a, the second sub-pixels 121b, and the third sub-pixels 121c are respectively used to emit light of different colors. The first sub-pixels 121a are disposed in a manner corresponding to the first isolation openings 13b1, the second sub-pixels 121b are disposed in a manner corresponding to the second isolation openings 13b2, and the third sub-pixels 121c are disposed in a manner corresponding to the third isolation openings 13b3.

In one embodiment, the active area 10a includes a plurality of second regions 10al arranged in an array; each of the second regions 10al includes a plurality of sub-pixels 121, the plurality of sub-pixels 121 including a plurality of first sub-pixels 121a, a plurality of second sub-pixels 121b, and a plurality of third sub-pixels 121c; the second region 10al includes at least one first sub-region 10a11 and at least one second sub-region 10a12, the second sub-region 10a12 including at least one first sub-pixel 121a, at least one second sub-pixel 121b, and at least one third sub-pixel 121c; the first regions 10b1 located in the light-transmitting active area 10b correspond to the second regions 10al located in the active area 10a; and the opening area 10b11 corresponds to the first sub-region 10a11, the pixel area 10b12 corresponds to the second sub-region 10a12, and an arrangement rule of sub-pixels 121 in the pixel area 10b12 is the same as an arrangement rule of pixels in the second sub-region 10a12.

It should be noted that the display panel 10 some embodiments may be the same as the display panel 10 in the other embodiments, and embodiments of the present application will not be described in detail here. The display apparatus can ensure the display effect of the light-transmitting active area, while increasing the light transmittance of the light-transmitting active area.

The display apparatus may be a notebook computer, a mobile phone, a wireless device, a personal digital assistant (PDA), a handheld or portable computer, a GPS receiver/navigator, a camera, an MP4 video player, a video camera, a game console, a watch, a clock, a calculator, a television monitor, a flat panel display, a computer monitor, a vehicle display (e.g., an odometer display, etc.), a navigation device, a cockpit controller and/or display, a camera view display (e.g., a display for a rearview camera in a vehicle), an electronic photograph, an electronic billboard or signboard, a projector, or the like.

When the terms “comprise”, “have”, and “include” are used as described herein, unless otherwise clearly defined, for example, expressions “only” and “composed of . . . ”, another component may further be added. Unless otherwise mentioned, the singular form may include plural forms and should not be construed as the number thereof being one.

The embodiments may be randomly combined. To make the description concise, not all possible combinations of the features in the above embodiments are described. However, the combinations of these features shall be considered as falling within the scope recorded in this specification provided that no conflict exists.

The above embodiments merely represent several implementations of the present application, giving specifics and details thereof, but should not be understood as limiting the scope of patent of the present application. It should be noted that several alterations and improvements can be made without departing from the spirit of the present application and these would all fall within the scope of protection of the present application. Therefore, the scope of protection of the present patent application shall be in accordance with the appended claims.

1. A display panel, comprising:
a light-transmitting active area, the light-transmitting active area comprising a plurality of first regions, and the plurality of first regions being arranged in an array, wherein each first region comprises at least one opening area and at least one pixel area, and the display panel is provided with at least one sub-opening in the opening area;
the pixel area comprises at least one first sub-pixel, at least one second sub-pixel, and at least one third sub-pixel; and
the first sub-pixel, the second sub-pixel, and the third sub-pixel are respectively used to emit light of different colors.

2. The display panel according to claim 1, wherein a size of the opening area is greater than or equal to a size of a sub-pixel, wherein the sub-pixel is one of the first sub-pixel, the second sub-pixel, or the third sub-pixel.

3. The display panel according to claim 1, wherein the pixel area comprises at least one pixel unit, wherein the pixel unit comprises one first sub-pixel, one second sub-pixel, and one third sub-pixel, or the pixel unit comprises one first sub-pixel, one second sub-pixel, and two third sub-pixels.

4. The display panel according to claim 3, wherein
the opening area is provided with a plurality of sub-openings, and a number of sub-openings is an integer multiple of a number of sub-pixels contained in one pixel unit, the sub-pixels comprising the first sub-pixel, the second sub-pixel, and the third sub-pixel;
the plurality of sub-openings comprise at least one first sub-opening, at least one second sub-opening, and at least one third sub-opening; the first sub-opening corresponds to the first sub-pixel; the second sub-opening corresponds to the second sub-pixel; and the third sub-opening corresponds to the third sub-pixel; and
an arrangement rule of the plurality of sub-openings in the opening area is the same as an arrangement rule of the sub-pixels in one pixel unit.

5. The display panel according to claim 3, wherein
a size of the opening area is greater than or equal to a size of one pixel unit area in the corresponding first region, and all the sub-pixels in the pixel unit are located in the pixel unit area;
the opening area is provided with one sub-opening; a size of the sub-opening is greater than or equal to a sum of sizes of all the sub-pixels in the pixel unit in the corresponding first region;
the pixel area is provided with a plurality of pixel units, and a morphology of the opening area is the same as a morphology of a pixel unit area corresponding to one of the pixel units;
the first region comprises a plurality of opening areas; and
the opening areas in the same first region have a same shape, or the opening areas in the same first region have different shapes.

6. The display panel according to claim 5, wherein the pixel unit comprises:
one first sub-pixel, one second sub-pixel, and one third sub-pixel, and centroids of the first sub-pixel, the second sub-pixel, and the third sub-pixel in the same pixel unit are connected to form a triangle; and
the shape of the opening area is triangular; or the shape of the opening area is T-shaped.

7. The display panel according to claim 5, wherein the pixel unit comprises:
one first sub-pixel, one second sub-pixel, and one third sub-pixel, in the same pixel unit, the first sub-pixel and the second sub-pixel are arranged along a column direction, the third sub-pixel is located on a side of the first sub-pixel and the second sub-pixel, and along a row direction, an orthographic projection of the third sub-pixel on a plane perpendicular to the row direction overlaps with an orthographic projection of the first sub-pixel on the plane perpendicular to the row direction; the orthographic projection of the third sub-pixel on the plane perpendicular to the row direction overlaps with an orthographic projection of the second sub-pixel on the plane perpendicular to the row direction;
a distance between a side of the first sub-pixel away from the second sub-pixel and a side of the second sub-pixel away from the first sub-pixel is equal to a length of the third sub-pixel in the column direction; and
the shape of the opening area is rectangular.

8. The display panel according to claim 5, wherein the pixel unit comprises:
one first sub-pixel, one second sub-pixel, and two third sub-pixels; the first sub-pixel and the second sub-pixel are arranged along a first column, and the two third sub-pixels are arranged along a second column;
the first sub-pixel and the third sub-pixel are not in a same row, and the second sub-pixel and the third sub-pixel are not in a same row; and
the shape of the opening area is Z-shaped.

9. The display panel according to claim 1, wherein the display panel further comprises:
at least one active area located on a side of the light-transmitting active area, the active area comprising a plurality of second regions arranged in an array; each of the second regions comprises a plurality of sub-pixels, the plurality of sub-pixels comprising a plurality of first sub-pixels, a plurality of second sub-pixels, and a plurality of third sub-pixels; and the second region comprises at least one first sub-region and at least one second sub-region, the second sub-region comprises at least one first sub-pixel, at least one second sub-pixel, and at least one third sub-pixel;
the first regions located in the light-transmitting active area correspond to the second regions located in the active area; the opening area corresponds to the first sub-region, the pixel area corresponds to the second sub-region, and an arrangement rule of sub-pixels in the pixel area is the same as an arrangement rule of pixels in the second sub-region; and
the first sub-region comprises at least one first sub-pixel, at least one second sub-pixel, and at least one third sub-pixel.

10. The display panel according to claim 9, wherein the pixel area comprises at least one pixel unit, wherein the pixel unit comprises one first sub-pixel, one second sub-pixel, and one third sub-pixel, or the pixel unit comprises one first sub-pixel, one second sub-pixel, and two third sub-pixels;
the first sub-region comprises at least one pixel unit;
a plurality of the second regions are arranged along a first direction;
a plurality of the second regions are arranged along a second direction, the second direction intersecting with the first direction;
a plurality of the first regions are arranged along the first direction or the second direction; and
among a plurality of the first regions, opening areas in any two of the first regions have same relative positions in the corresponding first regions; or opening areas in at least two of the first regions have different relative positions in the corresponding first regions.

11. The display panel according to claim 9, wherein the first region comprises:
one opening area;
the pixel area comprises a plurality of pixel units, wherein the pixel unit comprises one first sub-pixel, one second sub-pixel, and one third sub-pixel;
the pixel area comprises three pixel units;
the first sub-region corresponding to the opening area comprises one pixel unit; and the second sub-region comprises three pixel units; and
centroids of the first sub-pixel, the second sub-pixel, and the third sub-pixel in the same pixel unit are connected to form a triangle; along a first direction, the first sub-pixel, the second sub-pixel, and the third sub-pixel are sequentially arranged, and along a second direction, a plurality of the first sub-pixels are sequentially arranged, a plurality of the second sub-pixels are sequentially arranged, and a plurality of the third sub-pixels are sequentially arranged; the second direction intersects with the first direction; and the shape of the opening area is triangular; or the shape of the opening area is T-shaped; or along a second direction, the first sub-pixel and the second sub-pixel are sequentially arranged, the third sub-pixel is sequentially arranged, and in the same pixel unit, along the first direction, an orthographic projection of the third sub-pixel on a plane perpendicular to the first direction overlaps with an orthographic projection of the first sub-pixel on the plane perpendicular to the first direction; the orthographic projection of the third sub-pixel on the plane perpendicular to the first direction overlaps with an orthographic projection of the second sub-pixel on the plane perpendicular to the first direction; the second direction intersects with the first direction; and the shape of the opening area is rectangular.

12. The display panel according to claim 9, wherein the pixel area comprises:
at least one pixel unit, wherein the pixel unit comprises one first sub-pixel, one second sub-pixel, and two third sub-pixels;
the first sub-region corresponding to the opening area comprises at least one pixel unit;
the second region comprises a plurality of pixel units; two first sub-pixels are located at two first vertices of a first virtual quadrilateral, and two second sub-pixels are located at two second vertices of the first virtual quadrilateral; the two first vertices and the two second vertices are disposed alternately and spaced apart from each other;
the third sub-pixel is located within the first virtual quadrilateral;
the first virtual quadrilateral is an isosceles trapezoid;
the pixel area comprises a plurality of pixel units; and
the shape of the opening area is Z-shaped.

13. The display panel according to claim 9, wherein the first region comprises:
a plurality of opening areas; the second region comprises a plurality of first sub-regions; the second region comprises a plurality of pixel units; the pixel unit comprises one first sub-pixel, one second sub-pixel, and one third sub-pixel; or the pixel unit comprises one first sub-pixel, one second sub-pixel, and two third sub-pixels; and a part of sub-pixels in at least one of the first sub-regions is a part of one pixel unit, and another part of the sub-pixels in the first sub-region is a part of another pixel unit;
the plurality of the opening areas comprise at least one first sub-opening area and at least one second sub-opening area;
the at least one first sub-opening area or the at least one second sub-opening area is adjacent to the pixel area;
the plurality of the first sub-regions comprise at least one sub-region I and at least one sub-region II, wherein the sub-region I corresponds to the first sub-opening area, and the sub-region II corresponds to the second sub-opening area; and
a part of sub-pixels in at least one of the first sub-regions that corresponds to one opening area is a part of one pixel unit, and another part of the sub-pixels in the first sub-region is a part of another pixel unit.

14. The display panel according to claim 13, wherein the pixel area comprises:
a plurality of pixel units, and the first sub-opening area and the second sub-opening area are both adjacent to the corresponding pixel area;
the plurality of the opening areas comprise one first sub-opening area and one second sub-opening area;
the sub-region I corresponding to the first sub-opening area comprises one pixel unit, and the sub-region II corresponding to the second sub-opening area comprises one pixel unit;
the pixel area comprises two pixel units, wherein in the two pixel units in the pixel area, one of the pixel units is located on a side of the first sub-opening area along a first direction, and the second sub-opening area is located on a side of the pixel unit along a second direction; and the other pixel unit is located on a side of the first sub-opening area along the second direction, and the second sub-opening area is located on a side of the other pixel unit along the first direction; or the two pixel units are adjacent along the first direction, and the first sub-opening area and the second sub-opening area are adjacent along the first direction; and the second direction intersects with the first direction;
or the pixel area comprises four pixel units, wherein three pixel units in the pixel area are sequentially arranged along the first direction, the first sub-opening area and the second sub-opening area are spaced apart along the first direction, and the first sub-opening area and the second sub-opening area are located on a side of the three pixel units along the second direction; and the second direction intersects with the first direction; and
the shapes of the first sub-opening area and the second sub-opening area are each triangular, Z-shaped, or T-shaped.

15. The display panel according to claim 10, wherein the pixel area comprises:
a plurality of pixel units, and the first region comprises a plurality of opening areas, the pixel unit being arranged on at least one side of the opening area along the first direction, or the pixel unit being arranged on at least one side of the opening area along the second direction;
the first sub-region corresponding to the opening area comprises one pixel unit; the second region corresponding to the first region comprises a plurality of pixel units, the plurality of pixel units being arranged in rows along the first direction and arranged in columns along the second direction;
in the first region, each pixel unit row is provided with one opening area; and in the first region, each pixel unit column is provided with one opening area;
or in the first region, among all pixel unit rows in the same first region, two opening areas are respectively provided in outermost pixel unit rows; and among all pixel unit columns in the same first region, two opening areas are respectively provided in outermost pixel unit columns; and
the shapes of the opening areas are each rectangular.

16. The display panel according to claim 9, wherein the display panel comprises:
a plurality of pixel groups arranged repeatedly; the pixel group comprises at least one first sub-pixel, at least one second sub-pixel, and at least one third sub-pixel; and the second region comprises at least one pixel group; or
the second region comprises a plurality of the pixel groups; and the first sub-region corresponding to the opening area comprises at least one of the pixel groups.

17. The display panel according to claim 1, wherein the display panel further comprises:
an isolation structure, wherein the isolation structure is disposed on a side of a substrate, and the isolation structure is provided with a plurality of isolation openings and a plurality of light-transmitting openings, at least part of a structure of a sub-pixel is disposed in a corresponding isolation opening, and the plurality of light-transmitting openings are disposed in a manner corresponding to sub-openings of a plurality of opening areas of the light-transmitting active area;
an orthographic projection of each light-transmitting opening on the substrate coincides with an orthographic projection of each corresponding opening area on the substrate;
the sub-pixel comprises a first electrode, a light-emitting functional portion, and a second electrode that are stacked in a direction away from the substrate, the second electrode being electrically connected to the isolation structure;
the isolation structure comprises an isolation body and a blocking portion that are stacked in the direction away from the substrate, an outer contour of an orthographic projection of the blocking portion on the substrate being located outside an outer contour of an orthographic projection of the isolation body on the substrate;
the isolation body comprises a conductive material, the second electrode being electrically connected to the isolation body; and
the isolation structure in the light-transmitting active area is provided with a plurality of opening groups, the plurality of opening groups being in one-to-one correspondence with the plurality of first regions, and each of the opening groups comprising a plurality of the isolation openings and at least one of the light-transmitting openings.

18. The display panel according to claim 17, wherein the display panel further comprises:
an array film layer, the array film layer being arranged between the substrate and the isolation structure;
the array film layer is provided with a plurality of pixel circuits, the plurality of pixel circuits being arranged in the active area and the light-transmitting active area, and the plurality of pixel circuits being electrically connected to a plurality of sub-pixels correspondingly; and
an orthographic projection of each pixel circuit disposed in the light-transmitting active area on the substrate does not overlap with an orthographic projection of each corresponding opening area on the substrate; or an orthographic projection of each pixel circuit located in the light-transmitting active area on the substrate partially overlaps with an orthographic projection of each corresponding opening area on the substrate, and the pixel circuit corresponding to an overlapping portion is configured as a transparent conductive film layer.

19. The display panel according to claim 18, wherein
the array film layer is further provided with a plurality of first signal lines, the plurality of first signal lines being arranged in the active area and the light-transmitting active area, and an orthographic projection of each first signal line disposed in the light-transmitting active area on the substrate being located within an orthographic projection of the pixel area on the substrate; and
the array film layer is further provided with a plurality of data signal lines, the plurality of data signal lines being arranged in the active area and the light-transmitting active area,
wherein an orthographic projection of each data signal line disposed in the light-transmitting active area on the substrate partially overlaps with an orthographic projection of a corresponding opening area on the substrate, and the data signal line corresponding to an overlapping portion is configured as a transparent conductive film layer.

20. A display apparatus, comprising:
a display panel, comprising:
a light-transmitting active area, the light-transmitting active area comprising a plurality of first regions, and the plurality of first regions being arranged in an array, wherein each first region comprises at least one opening area and at least one pixel area, and the display panel is provided with at least one sub-opening in the opening area;
the pixel area comprises at least one first sub-pixel, at least one second sub-pixel, and at least one third sub-pixel; and
the first sub-pixel, the second sub-pixel, and the third sub-pixel are respectively used to emit light of different colors.
